(19) United States
(12) Patent Application Publication
(10) Pub. No.: US 2026/0262183 A1
(43) Pub. Date: Sep. 3, 2026

(54) CONTROL METHOD AND APPARATUS

(71) Applicant: HUAWEI TECHNOLOGIES CO., LTD., Shenzhen, Guangdong (CN)

(72) Inventor: Jinquan Li, Beijing (CN)

(21) Appl. No.: 19/555,066

(22) Filed: Mar. 3, 2026

Related U.S. Application Data
(63) Continuation of application No. PCT/CN2024/094940, filed on May 23, 2024.

(30) Foreign Application Priority Data
Sep. 4, 2023 (CN) 202311138996.8

(51) Int. Cl. H05K 5/02

(52) U.S. Cl. CPC H05K 5/0247

(57) ABSTRACT

A control method and an apparatus are provided, and relate to the field of chip technologies, to reduce power consumption of a foldable device. The control apparatus includes: a processor, located on a first circuit board corresponding to a first screen in the foldable device, and configured to generate a control signal, where the control signal is used to control an operating mode of a connection apparatus; and a transmission interface, configured to send the control signal to the connection apparatus. The connection apparatus is located on a second circuit board corresponding to a second screen in the foldable device, and is configured to transmit a system signal between the first circuit board and the second circuit board. The control apparatus may send the control signal to the connection apparatus to control the operating mode of the connection apparatus, to adjust and control operating power of the connection apparatus.

### CROSS-REFERENCE TO RELATED APPLICATIONS

This application is a continuation of International Application No. PCT/CN2024/094940, filed on May 23, 2024, which claims priority to Chinese Patent Application No. 202311138996.8, filed on Sep. 4, 2023. The disclosures of the aforementioned applications are hereby incorporated by reference in their entireties.

### TECHNICAL FIELD

Embodiments of this application relate to the field of chip technologies, and in particular, to a control method and an apparatus.

### BACKGROUND

Foldable screens are a branch of flexible screens. A foldable screen can achieve 360-degree bending or even twisting. Compared with a common screen, the foldable screen in an unfolded state can provide a larger display area, to improve visual effect. When the foldable screen is in a folded state, the foldable screen is small in size, making it easy for a user to carry.

Currently, a foldable device uses a hardware design of two circuit boards: a primary circuit board and a secondary circuit board, and the primary circuit board and the secondary circuit board are connected through a flat cable to transmit signals of functional elements (for example, a speaker, a microphone, and a sensor). With an increasing quantity of functional elements included in the current foldable device, flat cables disposed between the primary circuit board and the secondary circuit board increase accordingly, consequently occupying larger internal space of the foldable device and limiting a structural design and a layout inside the foldable device. A connection apparatus with an aggregation transmission function is disposed between the primary circuit board and the secondary circuit board to replace the flat cable for signal transmission, so that a quantity of flat cables between the primary circuit board and secondary circuit board can be reduced, and limitations on the structural design and the layout inside the foldable device are alleviated. However, power consumption of the foldable device is increased, and a battery life of the foldable device is reduced.

Therefore, how to reduce the power consumption of the foldable device is one of urgent problems that need to be resolved by a person skilled in the art.

### SUMMARY

Embodiments of this application provide a control method and an apparatus, to reduce power consumption of a foldable device. To achieve the foregoing objectives, the following technical solutions are used in embodiments of this application.

According to a first aspect, an embodiment of this application provides a control apparatus for a connection apparatus in a foldable device. The control apparatus includes: a processor, located on a first circuit board corresponding to a first screen in the foldable device, and configured to generate a control signal, where the control signal is used to control an operating mode of the connection apparatus; and a transmission interface, configured to send the control signal to the connection apparatus. The connection apparatus is located on a second circuit board corresponding to a second screen in the foldable device, and is configured to transmit a system signal between the first circuit board and the second circuit board.

It can be learned that, the control apparatus provided in this embodiment of this application may send the control signal to the connection apparatus to control the operating mode of the connection apparatus, to adjust and control operating power of the connection apparatus, thereby reducing power consumption of the foldable device. For example, when there is no system signal transmission requirement for the connection apparatus of the foldable device, the control signal may be sent to the connection apparatus to control the connection apparatus to enter a sleep mode, thereby reducing the power consumption of the foldable device (the connection apparatus).

In a possible implementation, the control signal includes a sleep control signal. The sleep control signal is used to control the connection apparatus to enter the sleep mode, and the connection apparatus stops transmitting the system signal in the sleep mode.

It may be understood that, the sleep control signal is used to control the connection apparatus to enter the sleep mode, so that the connection apparatus stops transmitting the system signal, thereby reducing the power consumption of the connection apparatus of the foldable device.

In a possible implementation, the processor is specifically configured to generate the sleep control signal when it is determined that the system signal does not need to be transmitted between the first circuit board and the second circuit board.

It may be understood that, when it is determined that the system signal does not need to be transmitted between the first circuit board and the second circuit board, the sleep control signal is generated, so that the connection apparatus stops transmitting the system signal. This does not affect system signal transmission while reducing the power consumption of the connection apparatus of the foldable device.

In a possible implementation, the processor is further specifically configured to control the transmission interface to enter a sleep mode. In this way, the power consumption of the connection apparatus of the foldable device is further reduced.

For example, the transmission interface may be a peripheral component interconnect express (peripheral component interconnect express, PCIe) interface or an aggregation chip. The aggregation chip may include a multiplexer (multiplex, MUX).

In a possible implementation, the control signal includes a working control signal. The working control signal is used to control the connection apparatus to enter a working mode, and the connection apparatus is configured to transmit the system signal in the working mode.

It may be understood that the working control signal is used to control the connection apparatus to enter the working mode, so that the connection apparatus transmits the system signal, thereby meeting a requirement for the foldable device to transmit the system signal through the connection apparatus.

In a possible implementation, the processor is specifically configured to generate the working control signal when it is determined that the system signal needs to be transmitted between the first circuit board and the second circuit board.

It may be understood that, the working control signal is generated only when it is determined that the system signal needs to be transmitted between the first circuit board and the second circuit board, so that the connection apparatus transmits the system signal, and the connection apparatus can work as required, thereby reducing working duration of the connection apparatus and reducing the power consumption of the connection apparatus of the foldable device.

In a possible implementation, the transmission interface is controlled to enter a working mode.

It may be understood that the transmission interface is controlled to enter the working mode, so that the transmission interface can transmit the system signal, and a requirement for the foldable device to transmit the control signal through the transmission interface can be met.

In a possible implementation, the connection apparatus is configured to: receive the system signal from the first circuit board, and convert the system signal into one or more element control signals. The one or more element control signals are used to control one or more functional elements on the second circuit board.

For example, the functional element may be a speaker, a microphone, a sensor, a memory card, a subscriber identity module (subscriber identity module, SIM) card, a vibration motor, a display, a touchscreen, a camera module, an antenna module, a fingerprint recognition module, a charging interface, or another functional element.

According to a second aspect, an embodiment of this application provides a connection apparatus for a foldable device. The connection apparatus is located on a second circuit board corresponding to a second screen in the foldable device, and includes: a signal transmission circuit, configured to transmit a system signal between a first circuit board and the second circuit board in the foldable device; and a controller, configured to receive a control signal from a control apparatus, and control an operating mode of the connection apparatus based on the control signal. The control apparatus is located on the first circuit board.

The control signal includes a sleep control signal. The sleep control signal is used to control the connection apparatus to enter a sleep mode. The signal transmission circuit is configured to: in the sleep mode, stop transmitting the system signal.

In a possible implementation, the control signal includes a working control signal. The working control signal is used to control the connection apparatus to enter a working mode. The signal transmission circuit is configured to: in the working mode, transmit the system signal.

In a possible implementation, the signal transmission circuit is configured to: receive the system signal from the first circuit board, and convert the system signal into the one or more element control signals. The one or more element control signals are used to control one or more functional elements on the second circuit board.

According to a third aspect, an embodiment of this application further provides an electronic device. The electronic device includes the control apparatus according to the first aspect or any possible implementation of the first aspect and the connection apparatus according to the second aspect or any possible implementation of the second aspect.

For example, the electronic device may be a foldable device.

According to a fourth aspect, an embodiment of this application further provides a control method. The method includes: generating a control signal, where the control signal is used to control an operating mode of a connection apparatus; and sending the control signal to the connection apparatus. The connection apparatus is located on a second circuit board corresponding to a second screen in a foldable device, and is configured to transmit a system signal between a first circuit board and the second circuit board.

In a possible implementation, the control signal includes a sleep control signal or a working control signal. The sleep control signal is used to control the connection apparatus to enter a sleep mode, and the connection apparatus stops transmitting the system signal in the sleep mode. The working control signal is used to control the connection apparatus to enter a working mode, and the connection apparatus is configured to transmit the system signal in the working mode.

According to a fifth aspect, an embodiment of this application further provides another control method. The method includes: receiving a control signal from a control apparatus; and controlling an operating mode of a connection apparatus based on the control signal. The control apparatus is located on a first circuit board.

In a possible implementation, the control signal includes a sleep control signal or a working control signal. The sleep control signal is used to control the connection apparatus to enter a sleep mode, and the connection apparatus stops transmitting a system signal in the sleep mode. The working control signal is used to control the connection apparatus to enter a working mode, and the connection apparatus transmits the system signal in the working mode.

According to a sixth aspect, an embodiment of this application further provides a chip, including a transmission interface and at least one processor. Optionally, the chip further includes a memory. The at least one processor is configured to execute code in the memory. When the at least one processor executes the code, the chip implements the method according to the fourth aspect or any possible implementation of the fourth aspect.

Optionally, the chip may be an integrated circuit.

For example, the chip may be a chip in a control apparatus used for a connection apparatus of a foldable device or a chip in a connection apparatus used for a foldable device.

According to a seventh aspect, an embodiment of this application further provides a computer-readable storage medium, configured to store a computer program. The computer program is used to implement the method according to the fourth aspect or any possible implementation of the fourth aspect.

According to an eighth aspect, an embodiment of this application further provides a computer program product including instructions. When the computer program product runs on a computer, the computer is enabled to implement the method according to the fourth aspect or any possible implementation of the fourth aspect.

The control apparatus, the computer storage medium, the computer program product, and the chip provided in the embodiments are all configured to perform the method provided above. Therefore, for beneficial effect that can be achieved, refer to beneficial effect in the method provided above. Details are not described herein again.

### BRIEF DESCRIPTION OF DRAWINGS

To describe technical solutions in embodiments of this application more clearly, the following briefly describes accompanying drawings used in descriptions of embodiments. It is clear that the accompanying drawings in the following descriptions show merely some embodiments of this application, and a person of ordinary skill in the art may still derive other accompanying drawings from these accompanying drawings without creative efforts.

FIG. 1 is a diagram of a structure of a foldable device according to an embodiment of this application;

FIG. 2 is a diagram of another structure of a foldable device according to an embodiment of this application;

FIG. 3 is a block diagram of a signal transmission principle according to an embodiment of this application;

FIG. 4 is another block diagram of a signal transmission principle according to an embodiment of this application;

FIG. 5 is still another block diagram of a signal transmission principle according to an embodiment of this application;

FIG. 6 is still another block diagram of a signal transmission principle according to an embodiment of this application;

FIG. 7 is still another block diagram of a signal transmission principle according to an embodiment of this application;

FIG. 8 is a schematic flowchart of a control method according to an embodiment of this application;

FIG. 9 is a schematic flowchart of another control method according to an embodiment of this application; and

FIG. 10 is a diagram of a structure of a chip according to an embodiment of this application.

### DESCRIPTION OF EMBODIMENTS

The following clearly and describes technical solutions in embodiments of this application with reference to the accompanying drawings in embodiments of this application. It is clear that the described embodiments are merely some rather than all of embodiments of this application. All other embodiments obtained by a person of ordinary skill in the art based on embodiments of this application without creative efforts shall fall within the protection scope of embodiments of this application.

Term “and/or” in this specification describes only an association relationship for describing associated objects and indicates that three relationships may exist. For example, A and/or B may indicate the following three cases: Only A exists, both A and B exist, and only B exists.

In this specification and the accompanying drawings of embodiments of this application, the terms “first”, “second”, and the like are intended to distinguish between different objects or distinguish between different processing of a same object, but do not indicate a particular order of the objects.

In addition, terms “includes”, “have”, and any other variants thereof mentioned in descriptions of embodiments of this application are intended to cover a non-exclusive inclusion. For example, a process, a method, a system, a product, or a device that includes a series of steps or units is not limited to the listed steps or units, but optionally further includes another unlisted step or unit, or optionally further includes another inherent step or unit of the process, the method, the product, or the device.

It should be noted that, in descriptions of embodiments of this application, terms such as “example” or “for example” indicate giving an example, an illustration, or a description. Any embodiment or design solution described as “example” or “for example” in embodiments of this application should not be explained as being more preferred or having more advantages than another embodiment or design solution. Exactly, use of the term such as “example” or “for example” is intended to present a related concept in a specific manner.

Foldable screens are a branch of flexible screens. A foldable screen can achieve 360-degree bending or even twisting. Compared with a common screen, the foldable screen in an unfolded state can provide a larger display area, to improve visual effect. When the foldable screen is in a folded state, the foldable screen is small in size, making it easy for a user to carry.

Currently, a foldable device uses a hardware design of two circuit boards: a primary circuit board and a secondary circuit board, and the primary circuit board and the secondary circuit board are connected through a flat cable to transmit signals of functional elements (for example, a speaker, a microphone, and a sensor). With an increasing quantity of functional elements included in the current foldable device, flat cables disposed between the primary circuit board and the secondary circuit board increase accordingly, consequently occupying larger internal space of the foldable device and limiting a structural design and a layout inside the foldable device. A connection apparatus with an aggregation transmission function is disposed between the primary circuit board and the secondary circuit board to replace the flat cable for signal transmission, so that a quantity of flat cables between the primary circuit board and secondary circuit board can be reduced, and limitations on the structural design and the layout inside the foldable device are alleviated. However, power consumption of the foldable device is increased, and a battery life of the foldable device is reduced.

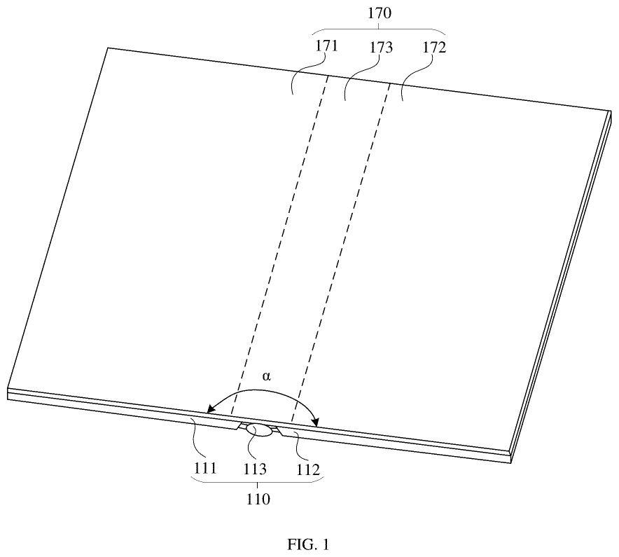

Therefore, an embodiment of this application provides a control apparatus for a connection apparatus in a foldable device. The control apparatus is applicable to the foldable device, which can reduce power consumption of the foldable device. FIG. 1 is a diagram of a structure of the foldable device in an unfolded state. As shown in FIG. 1, the foldable device provided in this embodiment of this application includes a housing 110 and a flexible display 170.

The housing 110 forms an appearance of the foldable device. The housing 110 may be a metal housing, for example, made of magnesium alloy, aluminum alloy, stainless steel, or another metal. Alternatively, the housing 110 may be a plastic housing, a glass housing, a ceramic housing, or the like, but is not limited thereto. The housing 110 usually includes structures such as a side frame, a middle frame, and a rear cover. A mounting cavity is provided inside the housing 110. Various electronic elements are mounted in the mounting cavity, for example, including a circuit board, a processor disposed on the circuit board, a battery, and various functional elements such as a camera, a flash, a microphone, and a speaker, but not limited thereto.

The foldable device further includes the flexible display 170 disposed on the housing 110. The flexible display 170 serves as a front panel of the foldable device, and encloses the mounting cavity with the housing 110. The flexible display 170 forms a display surface of the foldable device and is configured to: display information such as an image and a text, and provide information interaction. The flexible display 170 has flexible and bendable characteristics. For example, the flexible display 170 may be an organic light-emitting diode (organic light-emitting diode, OLED) display, an active-matrix organic light-emitting diode (active-matrix organic light-emitting diode, AMOLED) display, a mini light-emitting diode (mini organic light-emitting diode) display, a micro light-emitting diode (micro organic light-emitting diode) display, a micro organic light-emitting diode (micro organic light-emitting diode) display, a quantum dot light-emitting diode (quantum dot light-emitting diode, QLED) display, or the like, but is not limited thereto.

As shown in FIG. 1, the housing 110 includes a plurality of parts, including a first housing 111, a foldable mechanism 113, and a second housing 112 that are sequentially connected. The foldable mechanism 113 is deformable, allowing the first housing 111 and the second housing 112 to unfold or fold relative to each other.

The display 170 includes a first screen 171, a bent portion 173, and a second screen 172 that are sequentially connected. The first housing 111 is fastened to the first screen 171. The second housing 112 is fastened to the second screen 172. The foldable mechanism 113 directly faces the bent portion 173.

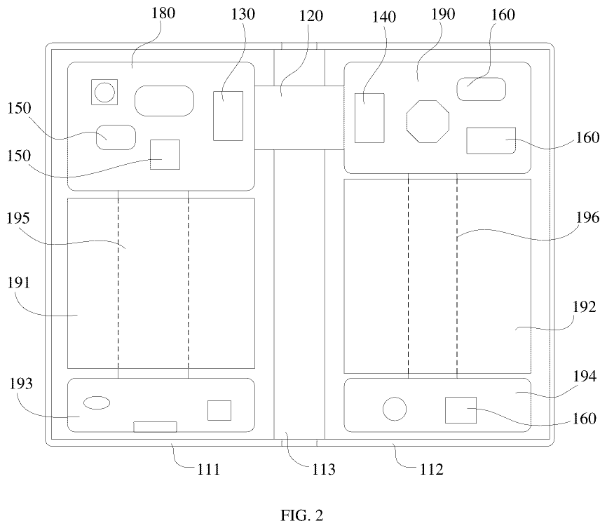

FIG. 2 is a rear view of the foldable device shown in FIG. 1 after a cover is removed. As shown in FIG. 2, in this embodiment of this application, the foldable device further includes a first flexible circuit board 120, a first circuit board 180, and a second circuit board 190 that are disposed in the housing 110. The first circuit board 180 is a circuit board corresponding to the first screen 171, and the first circuit board 180 is disposed in the first housing 111. The second circuit board 190 is a circuit board corresponding to the second screen 172, and the second circuit board 190 is disposed in the second housing 112. The first flexible circuit board 120 penetrates the foldable mechanism 113 to connect the first circuit board 180 and the second circuit board 190, to achieve signal conduction between the first circuit board 180 and the second circuit board 190.

As shown in FIG. 2, in this embodiment of this application, a first battery 191 and a first sub-board 193 are further disposed inside the first housing 111. The first circuit board 180, the first battery 191, and the first sub-board 193 are sequentially stacked from top to bottom, to form a conventional three-segment design architecture. The first circuit board 180 and the first sub-board 193 are electrically connected through a third flexible circuit board 195. The third flexible circuit board 195 is clamped between the first battery 191 and the foldable middle frame.

Similarly, a second battery 192 and a second sub-board 194 are further disposed inside the second housing 112. The second circuit board 190, the second battery 192, and the second sub-board 194 are sequentially stacked from top to bottom, to form a conventional three-segment design architecture. The second circuit board 190 and the second sub-board 194 are electrically connected through a second flexible circuit board 196. The second flexible circuit board 196 is clamped between the second battery 192 and the foldable middle frame.

Optionally, in another implementation, the third flexible circuit board 195 and the second flexible circuit board 196 may alternatively be disposed between the battery and the rear cover. For example, the third flexible circuit board 195 is clamped between the first battery 191 and a rear cover of the first housing 111, and the second flexible circuit board 196 is clamped between the second battery 192 and a rear cover of the second housing 112.

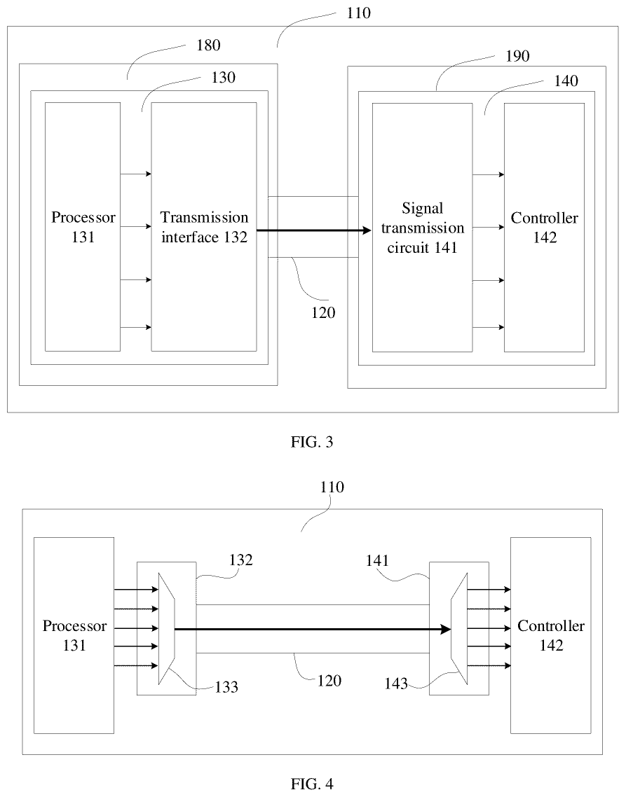

FIG. 3 is a block diagram of a signal transmission principle of a foldable device according to an embodiment of this application. As shown in FIG. 2 and FIG. 3, in this embodiment of this application, a control apparatus 130 is disposed on a first circuit board 180, and a connection apparatus 140 is disposed on a second circuit board 190. The control apparatus 130 and the connection apparatus 140 are used in conjunction, to transmit a system signal between the first circuit board 180 and the second circuit board 190.

In a possible implementation, the connection apparatus 140 is specifically configured to: receive a system signal from the first circuit board 180, and convert the system signal into one or more element control signals. The one or more element control signals are used to control one or more functional elements on the second circuit board 190. Specifically, each element control signal may control turn-on, turn-off, a working status, or the like of a corresponding element.

In a possible implementation, the control apparatus 130 is specifically configured to receive a system signal from the second circuit board 180. The system signal may be obtained by aggregating one or more data signals. For example, the system signal may be obtained by aggregating data signals collected by sensor components such as a brightness sensor, a temperature sensor, a pressure sensor, an acceleration sensor, and a gyroscope.

Correspondingly, the connection apparatus 140 may generate a corresponding element control signal based on the system signal from the second circuit board 180.

For example, the connection apparatus 140 may generate a corresponding element control signal based on a data signal from a brightness sensor in the second circuit board 180, to adjust brightness of a flexible display 170.

For example, the functional element may be a speaker, a microphone, a sensor, a memory card, a SIM card, a vibration motor, a display, a touchscreen, a camera module, an antenna module, a fingerprint recognition module, a charging interface, or another functional element.

For example, the system signal may include data signals of buses such as an inter-integrated circuit bus (inter-integrated circuit, I2C), a serial peripheral interface (serial peripheral interface, SPI), an integrated interchip sound (integrated interchip sound, I2S) bus, or a general purpose input/output (general purpose input/output, GPIO).

It should be noted that the connection apparatus 140 uses a first flexible circuit board 120 as a unified transmission line, and converts a system signal transmitted by the transmission line into signals of a plurality of working components on a second screen, which is equivalent to performing a one-to-many signal mapping. Such conversion does not require arrangement of a plurality of lines on the foldable device, so that transmission lines of the foldable device are centralized, and a space size of the transmission lines is reduced, thereby simplifying a hinge design of a foldable device, effectively reducing impact of the transmission lines on reliability of the foldable device, and improving overall strength of the foldable device. In other words, in this embodiment of this application, the connection apparatus 140 uses the first flexible circuit board 120 as the unified transmission line, to reduce design difficulty of a foldable mechanism of a foldable terminal device. This further helps improve reliability of the foldable mechanism and mechanical strength of the foldable device.

As shown in FIG. 3, the control apparatus 130 includes a processor 131 and a transmission interface 132.

The processor 131 is configured to generate a control signal. The control signal is used to control an operating mode of the connection apparatus 140.

For example, the processor 131 may be a microcontroller unit (microcontroller unit, MCU).

The transmission interface 132 is configured to send the control signal to the connection apparatus 140.

It may be understood that, in this embodiment of this application, “send information to . . . (for example, a connection apparatus)” or a related illustration in the accompanying drawings may be understood as that a destination end of the information is the connection apparatus, and may include directly or indirectly sending the information to the connection apparatus. “Receive information from . . . (for example, a connection apparatus)”, “receive information that is from . . . (for example, a connection apparatus)”, or a related illustration in the accompanying drawings may be understood as that a source end of the information is the connection apparatus, and may include directly or indirectly receiving the information from the connection apparatus. Necessary processing, for example, format conversion, may be performed on the information being sent between the source end and the destination end, but the destination end may understand valid information from the source end. Similar descriptions in embodiments of this application may be understood similarly. Details are not described herein again.

In a possible implementation, the control signal includes a sleep control signal.

The sleep control signal is used to control the connection apparatus 140 to enter a sleep mode, and the connection apparatus 140 stops transmitting the system signal in the sleep mode.

It should be noted that the connection apparatus may enter the sleep mode by reducing a clock frequency, reducing an operating current, or the like, to reduce operating power consumption. In other words, after the connection apparatus enters the sleep mode from a working mode, the clock frequency, the working current, and the operating power consumption of the connection apparatus are reduced in comparison with the working mode. After entering the sleep mode, the connection apparatus cannot continue receiving the system signal.

The connection apparatus 140 may determine a current mode of the connection apparatus 140 through a status register. For example, when a value of the status register is 1, the connection apparatus is in the working mode; and when a value of the status register is 0, the connection apparatus is in the sleep mode.

In a possible implementation, the processor 131 is specifically configured to generate the sleep control signal when it is determined that the system signal does not need to be transmitted between the first circuit board and the second circuit board.

In a possible implementation, the processor 131 is further configured to control the transmission interface to enter a sleep mode.

For example, the processor 131 may control the transmission interface 132 to enter the sleep mode after the transmission interface 132 sends the sleep control signal to the connection apparatus 140.

In a possible implementation, the control signal includes a working control signal.

The working control signal is used to control the connection apparatus 140 to enter the working mode, and the connection apparatus 140 is configured to transmit the system signal in the working mode. After entering the working mode, the connection apparatus can transmit the system signal.

It should be noted that the connection apparatus may enter the working mode by increasing the clock frequency, increasing the working current, or the like. In other words, after the connection apparatus enters the working mode from the sleep mode, the clock frequency, the working current, and the operating power consumption of the connection apparatus are also increased.

In a possible implementation, the processor 131 is specifically configured to generate the working control signal when it is determined that the system signal needs to be transmitted between the first circuit board and the second circuit board.

For example, the processor 131 may generate the working control signal when a service such as operator network authentication, fixed dialing, SIM card file operations, SIM card presence status query, or SIM card initialization is performed on the foldable device.

In a possible implementation, the processor 131 is further configured to control the transmission interface to enter a working mode.

For example, the processor 131 may generate the working control signal and control the transmission interface 132 to enter the working mode when it is determined that the system signal needs to be transmitted between the first circuit board and the second circuit board, so that the transmission interface 132 can send the working control signal to the connection apparatus 140.

In a possible implementation, the control signal includes a power-off control signal.

The power-off control signal is used to control the connection apparatus 140 to be powered off. In a power-off state, the connection apparatus 140 stops transmitting the system signal.

In a possible implementation, the processor 131 is specifically configured to generate the power-off control signal when it is determined that the system signal does not need to be transmitted between the first circuit board and the second circuit board and the connection apparatus is in the sleep mode for duration exceeding preset duration.

As shown in FIG. 3, the connection apparatus 140 includes a signal transmission circuit 141 and a controller 142.

The signal transmission circuit 141 is configured to transmit the system signal between the first circuit board and the second circuit board in the foldable device.

The controller 142 is configured to: receive the control signal from the control apparatus 130, and control the operating mode of the connection apparatus based on the control signal.

In a possible implementation, the controller 142 may also receive a control signal sent by another component on the first circuit board 180.

In a possible implementation, the signal transmission circuit 141 is specifically configured to: receive the system signal from the first circuit board, and convert the system signal into the one or more element control signals. The one or more element control signals are used to control the one or more functional elements on the second circuit board.

In a possible implementation, the signal transmission circuit 141 is configured to: in the sleep mode, stop transmitting the system signal.

For example, after receiving the sleep control signal, the controller 142 may control the signal transmission circuit 141 to be powered off.

In a possible implementation, the signal transmission circuit 141 is configured to: in the working mode, transmit the system signal.

For example, after receiving the working control signal, the controller 142 may control the signal transmission circuit 141 to be powered on.

As shown in FIG. 3, the connection apparatus 140 includes the signal transmission circuit 141 and the controller 142.

FIG. 4 is another block diagram of a signal transmission principle of a foldable device according to an embodiment of this application. As shown in FIG. 4, a transmission interface 132 of a control apparatus 130 includes a first multiplexer 133. A signal transmission circuit 141 of a connection apparatus 140 includes a first demultiplexer (demultiplexer, DEMUX) 143.

The first multiplexer 133 is configured to: multiplex (generally referred to as performing convergence, aggregation, or combination on) a plurality of to-be-transmitted digital signals to obtain a system signal, and send the system signal to the connection apparatus 140 through a first flexible circuit board 120. It is easy to understand that the plurality of to-be-transmitted digital signals herein are digital signals that need to be transmitted between a first circuit board 180 and a second circuit board 190.

The first demultiplexer 143 and the first multiplexer 133 are used in conjunction. The first demultiplexer 143 is configured to: demultiplex (generally referred to as performing recovery, restoration, decomposition, or splitting on) the system signal obtained by multiplexing by the first multiplexer 133, and output element control signals.

Herein, the first multiplexer 133 can perform multiplexing processing on the plurality of digital signals based on preset logic. For example, a plurality of digital signals are multiplexed into one signal (inserted into corresponding time slots), and then transmitted to the first demultiplexer 143 through the first flexible circuit board 120. The first demultiplexer 143 restores the plurality of digital signals based on corresponding logic and distributes the plurality of digital signals to signal receivers. The signal receiver may be, for example, (a circuit for) a processor or a functional element.

According to the foldable device provided in this embodiment of this application, the first multiplexer 133 is disposed on the first circuit board 180, and the first demultiplexer 143 is disposed on the second circuit board 190. The two components are used in conjunction. The first multiplexer 133 located on the first circuit board 180 (namely, a signal input end) multiplexes the plurality of to-be-transmitted digital signals, and then sends the multiplexed digital signal to the second circuit board 190 through the first flexible circuit board 120. The first demultiplexer 143 located on the second circuit board 190 (namely, a signal output end) demultiplexes the multiplexed signal, and then transmits the demultiplexed digital signals to corresponding receivers, and therefore normal transmission of the plurality of digital signals is not affected.

Based on this, the foldable device provided in this embodiment of this application combines the plurality of digital signals for transmission over one physical channel by employing a multiplexing (multiplexing) technology, which can effectively utilize a communication line and reduce a quantity of physical channels required for signal transmission. The physical channel is disposed on the first flexible circuit board 120, and the quantity of physical channels is positively correlated with a size of the first flexible circuit board 120. Therefore, a reduction in the physical channels also reduces the size (for example, a width and/or a thickness) of the first flexible circuit board 120. In this way, layout space for another component in the foldable device is expanded, an internal structure of the foldable device is effectively optimized, and difficulty of a structural design and a layout inside the foldable device is reduced. This facilitates miniaturization and a light weight and thinning design of the foldable device, thereby improving user experience. In addition, because the size of the first flexible circuit board 120 is reduced, capacity of a battery is increased. This helps increase battery endurance capacity of the foldable device.

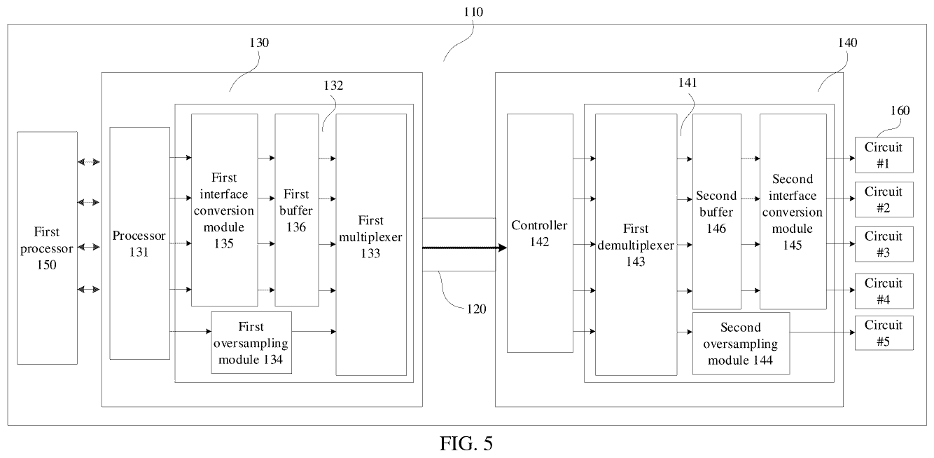

FIG. 5 is still another block diagram of a signal transmission principle of a foldable device according to an embodiment of this application. As shown in FIG. 5, the foldable device provided in this embodiment of this application further includes a first processor 150 and a plurality of first circuits 160. The first circuit 160 includes, for example, a circuit #1 to a circuit #5 in the figure. The plurality of first circuits 160 are disposed on a second circuit board 190. The first processor 150 is disposed on a first circuit board 180, and is configured to control actions of the plurality of first circuits 160. The first circuit 160 works based on a signal sent by the first processor 150. The first circuit 160 may be a circuit for a functional element, and is configured to control an action of the functional element. The first circuit 160 and the functional element may be in a one-to-one correspondence. For example, the circuit #1 to the circuit #5 in FIG. 5 respectively corresponds to (represents) circuits of five different functional elements.

In a possible implementation, the first processor 150 and the processor 131 may be a same processor.

Optionally, in another implementation, there may be one first circuit 160. This is not specifically limited in this application. In this embodiment of this application, the plurality of first circuits 160 are used as an example for description.

In this case, a first multiplexer 133 multiplexes at least a first signal sent by the first processor 150, a first demultiplexer 143 is configured to demultiplex the multiplexed first signal of the first processor 150, and the first circuit 160 works based on the signal demultiplexed by the first demultiplexer 143.

Specifically, as shown in FIG. 5, in this embodiment of this application, the first multiplexer 133 multiplexes a plurality of digital signals generated by the first processor 150, and then sends the multiplexed digital signal to the first demultiplexer 143 through a first flexible circuit board 120. The first demultiplexer 143 demultiplexes the multiplexed digital signal to restore the plurality of digital signals, and then distributes the plurality of digital signals to the plurality of first circuits 160, for example, the circuit #1 to the circuit #5 in FIG. 5. The first circuit 160 works based on the signals demultiplexed by the first demultiplexer 143.

Herein, the first processor 150 corresponds to the plurality of first circuits 160, and is configured to control the action of the first circuit 160. In other words, the first circuit 160 works based on the signal sent by the first processor 150. The first circuit 160 may be a circuit for a functional element, and may include a circuit for at least one of the following functional elements: a speaker, a microphone, a sensor, a memory card, a SIM card, a vibration motor, a display, a touchscreen, a camera module, an antenna module, a fingerprint recognition module, a charging interface (a universal serial bus (universal serial bus, USB) interface), and the like, but is not limited thereto.

The first processor 150 is configured to execute application program code in a memory, to invoke the first circuit 160 to implement a corresponding function. The first processor 150 may include one or more processing modules. Different processing modules may be independent components, or may be integrated into one or more processors. The first processor 150 may be specifically an integrated control chip, or may include a circuit including various active and/or passive components. The circuit is configured to perform a function that is of the first processor 150 and that is described in this embodiment of this application.

Optionally, the first processor 150 may include a plurality of processing modules, and each processing module may control an action of one or more first circuits 160. The first processor 150 may include various application processors (application processor, AP), a central processing unit (central processing unit, CPU), a graphics processing unit (graphics processing unit, GPU), an image signal processor (image signal processor, ISP), or the like, but is not limited thereto.

For example, the first processor 150 may include a central processing unit of the foldable device, and may control actions of the functional elements such as a memory card.

For another example, the first processor 150 may further include a multimedia driver module, and may control actions of the functional elements such as a display and a camera.

For another example, the first processor 150 may further include an audio driver module, and may control actions of the functional elements such as a speaker.

In this embodiment of this application, the first processor 150 is disposed on the first circuit board 180. The plurality of first circuits 160 are disposed on the second circuit board 190. The first flexible circuit board 120 penetrates a foldable mechanism 113, to achieve signal conduction between the first circuit board 180 and the second circuit board 190.

In this case, the plurality of to-be-transmitted digital signals generated by the first processor 150 are sequentially transmitted to the plurality of first circuits 160 through a control apparatus 130 (the first circuit board 180), the first flexible circuit board 120, and a connection apparatus 140 (the second circuit board 190).

Optionally, in another implementation, the plurality of first circuits 160 may alternatively be disposed on the first circuit board 180, and the first processor 150 is disposed on the second circuit board 190. In this case, the first multiplexer 133 may alternatively multiplex a plurality of digital signals sent by the plurality of first circuits 160, and then send the multiplexed digital signal to the first demultiplexer 143 through the first flexible circuit board 120. The first demultiplexer 143 demultiplexes the multiplexed digital signal to restore the plurality of digital signals, and then sends the plurality of digital signals to a corresponding processing module in the first processor 150.

Optionally, the first circuit 160 may be directly integrated into the second circuit board 190, or may be indirectly connected to the second circuit board 190 through a conducting wire or another flexible circuit board.

As shown in FIG. 5, in this embodiment of this application, for a digital signal whose transmission rate is lower than a preset threshold in the plurality of to-be-transmitted digital signals generated by the first processor 150, the first multiplexer 133 may collect the digital signal in an oversampling (oversampling) mode.

Specifically, a transmission interface 132 may further include a first oversampling module 134. The first oversampling module 134 is configured to: collect a digital signal whose transmission rate is lower than the preset threshold in the plurality of to-be-transmitted digital signals generated by the first processor 150 in the oversampling mode, and transmit the digital signal to the first multiplexer 133. Correspondingly, a signal transmission circuit 141 further includes a second oversampling module 144. The second oversampling module 144 is configured to: collect (a collection process is also referred to as recovery or restoration) a digital signal whose transmission rate is lower than the preset threshold in the plurality of digital signals output by the first demultiplexer 143, and distribute the digital signals to the first circuits 160.

According to the foldable device provided in this embodiment of this application, the first oversampling module 134 and the second oversampling module 144 that are used in conjunction are disposed, so that a level on a host (Host) side is transmitted to the connection apparatus 140 in the oversampling mode, and the connection apparatus 140 sends the level to a corresponding first circuit 160. A transparent transmission mode does not affect read/write driving of the first processor 150, and does not affect normal working of the first processor 150. In addition, an interface transparent transmission solution is employed to collect the digital signal and complete transparent transmission of data, without requiring additional development of a complex interface circuit, and a circuit structure requirement for an entire transmission link is low, thereby simplifying a design of a signal processor and reducing difficulty in developing the signal processor.

Selection of the preset threshold may be determined based on a processing capability of the first multiplexer 133, and the first multiplexer 133 can achieve accurate sampling (without distortion). Optionally, the preset threshold may be 3 to 8 megabit per second (million bits per second, Mbps), for example, may be 4 Mbps, 5 Mbps, 5.5 Mbps, 6 Mbps, or 7 Mbps.

For example, for a low-speed signal below 5 Mbps, the first oversampling module 134 may perform data sampling in the oversampling mode. For a high-speed signal above 5 Mbps, a clock of an interface may be used to collect data on the host side and send the collected data to the first multiplexer 133, and the first multiplexer 133 performs corresponding multiplexing processing (inserting into corresponding time slots based on preset logic).

As shown in FIG. 5, in this embodiment of this application, the transmission interface 132 further includes a first interface conversion module (Adaptor_H) 135. The signal transmission circuit 141 further includes a second interface conversion module (Adaptor_P) 145. The first interface conversion module 135 and the second interface conversion module 145 are used in conjunction.

The first interface conversion module 135 is configured to: collect a digital signal whose transmission rate is greater than or equal to the preset threshold in the plurality of to-be-transmitted digital signals generated by the first processor 150, and transmit the digital signal to the first multiplexer 133.

The second interface conversion module 145 is configured to collect and distribute a digital signal whose transmission rate is greater than or equal to the preset threshold in the plurality of digital signals output by the first demultiplexer 143.

The first interface conversion module 135 completes interface data sampling, and sends collected instructions to the first multiplexer 133. The first multiplexer 133 inserts the instructions into corresponding time slots based on the preset logic, and sends the instructions to the first demultiplexer 143 through the first flexible circuit board 120. The first demultiplexer 143 demultiplexes the multiplexed digital signal to restore the plurality of digital signals. The second interface conversion module 145 regenerates corresponding interface timing based on the received instructions, for example, regenerates corresponding SDIO, RFFE, or SPI interface timing, and sends the interface timing to corresponding first circuits 160.

Due to a processing capability limitation of the first multiplexer 133, data collection in the oversampling mode may not be achieved. For example, a processing rate of the first multiplexer 133 cannot reach more than twice a signal transmission rate. In this case, signal distortion is likely to occur. In this application, the first interface conversion module 135 may be used to collect a digital signal with a higher transmission rate. In addition, an interface conversion module (for example, an interface circuit) is configured to collect a digital signal with a higher transmission rate, so that a processing capability requirement for the first multiplexer 133 can also be reduced, thereby reducing a design difficulty of the signal processor.

As shown in FIG. 5, in this embodiment of this application, the transmission interface 132 further includes a first buffer 136. The first buffer 136 is configured to: buffer the digital signal collected by the first interface conversion module 135, and output the digital signal to the first multiplexer 133. The signal transmission circuit 141 further includes a second buffer 146. The second buffer 146 is configured to: buffer the digital signal output by the first demultiplexer 143, and output the digital signal to the second interface conversion module 145.

Due to the processing capability limitation of the first multiplexer 133, a data processing (sending) speed of the first interface conversion module 135 may not be matched. In this application, a buffer is disposed between the first interface conversion module 135 and the first multiplexer 133 to temporarily store data sent by the first interface conversion module 135, so that signals can be coordinated and buffered, and data transmission synchronization can be achieved. In addition, the first buffer 136 is disposed, so that instructions with higher transmission rates that are collected by the first interface conversion module 135 can be temporarily buffered, and the processing capability requirement for the first multiplexer 133 can be reduced, thereby reducing the design difficulty of the signal processor.

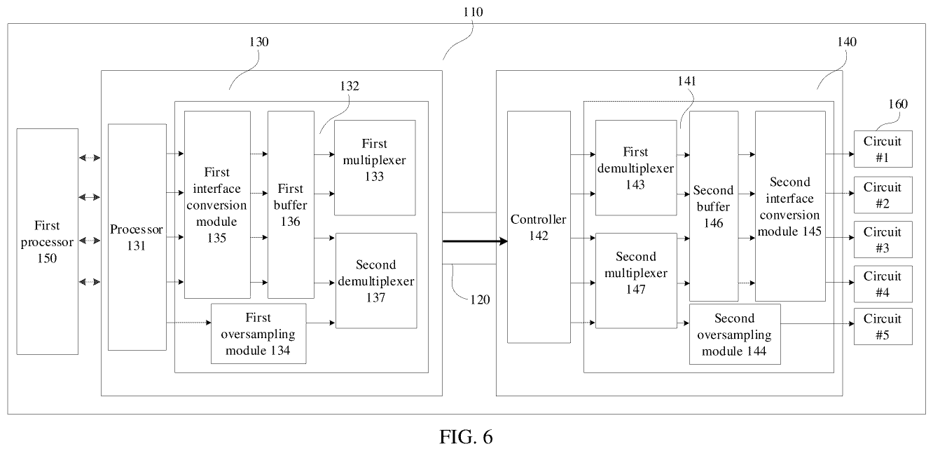

FIG. 6 is still another block diagram of a signal transmission principle of a foldable device according to an embodiment of this application. As shown in FIG. 6, compared with the embodiment shown in FIG. 5, in this embodiment of this application, a signal transmission circuit 141 further includes a second multiplexer 147, and a transmission interface 132 further includes a second demultiplexer 137.

The second multiplexer 147 is configured to: multiplex a plurality of to-be-transmitted digital signals generated by a plurality of first circuits 160, and send the multiplexed digital signal to a control apparatus 130 (a first circuit board 180) through a first flexible circuit board 120.

The second demultiplexer 137 is configured to: demultiplex the digital signal multiplexed by the second multiplexer 147, and output the digital signal to a first processor 150.

In other words, the first flexible circuit board 120 can achieve bidirectional transmission of the digital signals, and in either transmission direction, a multiplexing technology is employed to combine the plurality of digital signals for transmission over one physical channel. Therefore, a quantity of physical channels required for signal transmission can be further reduced, thereby further reducing a size of the first flexible circuit board 120 and facilitating a foldable design.

In this case, similar to a first oversampling module 134, a second oversampling module 144 is further configured to: collect a digital signal whose transmission rate is lower than a preset threshold in the plurality of to-be-transmitted digital signals generated by the first circuit 160 in an oversampling mode, and transmit the digital signals to the second multiplexer 147.

Similar to the second oversampling module 144, the first oversampling module 134 is further configured to collect: a digital signal whose transmission rate is lower than the preset threshold in the plurality of digital signals output by the second demultiplexer 137, and send the digital signals to the first processor 150 (distribute to processing modules of the first processor 150).

Further, similar to a first interface conversion module 135, a second interface conversion module 145 is further configured to: collect a digital signal whose transmission rate is greater than or equal to the preset threshold in the plurality of to-be-transmitted digital signals generated by the first circuit 160, and buffer the digital signals in a second buffer 146. The second multiplexer 147 inserts the digital signals into corresponding time slots based on preset logic, and the first flexible circuit board 120 sends the multiplexed digital signal to the second demultiplexer 137.

Similar to the second interface conversion module 145, the first interface conversion module 135 is further configured to: regenerate corresponding interface time sequences based on received instructions sent by the second demultiplexer 137, and send the corresponding interface time sequences to corresponding processing modules in the first processor 150.

It should be noted that, in this embodiment of this application, a first multiplexer 133, the first oversampling module 134, the first interface conversion module 135, a first buffer 136, and the second demultiplexer 137 are integrated together to form the transmission interface 132. In other words, the foregoing five components are equivalent to five modules of the transmission interface 132. In another implementation, the foregoing five components may be five independent components that are separately disposed on the first circuit board 180, some (not all) of the five components are integrated together, or one or more of the five components are integrated together with another element on the first circuit board 180. This is not specifically limited in this application.

Similarly, in this embodiment of this application, a first demultiplexer 143, the second oversampling module 144, the second interface conversion module 145, the second buffer 146, and the second multiplexer 147 are integrated together to form the signal transmission circuit 141. In other words, the foregoing five components are equivalent to five modules of the signal transmission circuit 141. In another implementation, the foregoing five components may be five independent components that are separately disposed on a second circuit board 190, some (not all) of the five components are integrated together, or one or more of the five components are integrated together with another element on the second circuit board 190. This is not specifically limited in this application.

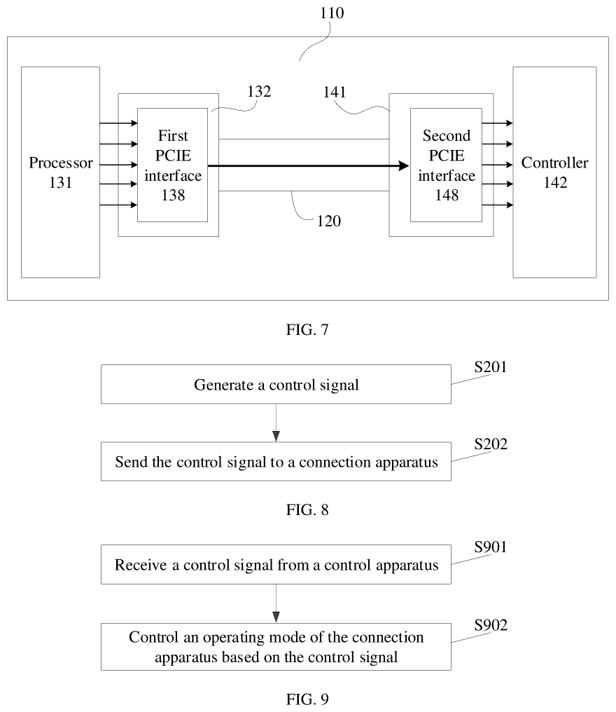

FIG. 7 is still another block diagram of a signal transmission principle of a foldable device according to an embodiment of this application. As shown in FIG. 7, a transmission interface 132 of a control apparatus 130 includes a first PCIE interface 138. A signal transmission circuit 141 of a connection apparatus 140 includes a second PCIE interface 148.

The first PCIE interface 138 is configured to: aggregate a plurality of to-be-transmitted digital signals to obtain a system signal, and send the system signal to the connection apparatus 140 through a first flexible circuit board 120.

The second PCIE interface 148 and the first PCIE interface 138 are used in conjunction. The second PCIE interface 148 is configured to: de-aggregate the system signal obtained by aggregating by the first PCIE interface 138, and output an obtained element control signal.

FIG. 8 shows a control method according to an embodiment of this application. The method may be performed by the control apparatus 130 in FIG. 2. As shown in FIG. 8, the method includes the following steps.
S201: Generate a control signal.

The control signal is used to control an operating mode of a connection apparatus.

For example, the control apparatus 130 may generate the control signal by using a processor 131.

In a possible implementation, the control signal includes a sleep control signal. The sleep control signal is used to control the connection apparatus to enter a sleep mode, and the connection apparatus stops transmitting a system signal in the sleep mode.

In a possible implementation, the control signal includes a working control signal. The working control signal is used to control the connection apparatus to enter a working mode, and the connection apparatus is configured to transmit the system signal in the working mode.
S202: Send the control signal to the connection apparatus.

For example, the control apparatus 130 may send the control signal to the connection apparatus 140 through a transmission interface 132.

FIG. 9 shows another control method according to an embodiment of this application. The method may be performed by the connection apparatus 140 in FIG. 2. As shown in FIG. 9, the method includes the following steps.
S901: Receive a control signal from a control apparatus.

For example, the connection apparatus 140 may receive the control signal from the control apparatus through a controller 142.
S902: Control an operating mode of the connection apparatus based on the control signal.

For example, the controller 142 of the connection apparatus may control the operating mode of the connection apparatus based on the control signal.

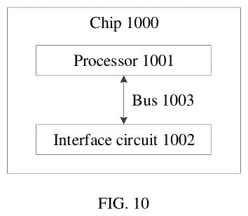

In a possible implementation, the control apparatus 130 may be a chip. FIG. 10 is a diagram of a structure of a chip 1000. The chip 1000 may be a chip in a control apparatus. The chip 1000 includes one or more processors 1001 and an interface circuit 1002.

Optionally, the chip 1000 may further include a bus 1003.

The processor 1001 may be an integrated circuit chip and has a signal processing capability. In an implementation process, steps in a memory control method can be implemented by using a hardware integrated logic circuit in the processor 1001, or by using instructions in a form of software.

Optionally, the processor 1001 may be a general-purpose processor, a digital signal processor (digital signal processor, DSP), an application-specific integrated circuit (application specific integrated circuit, ASIC), a field-programmable gate array (field-programmable gate array, FPGA) or another programmable logic device, a discrete gate or a transistor logic device, or a discrete hardware component. The processor 1001 may implement or perform the methods and steps that are disclosed in embodiments of this application. The general-purpose processor may be a microprocessor, or the processor may be any conventional processor or the like.

The interface circuit 1002 may be configured to send or receive data, instructions, or information. The processor 1001 may process the data, the instructions, or other information received through the interface circuit 1002, and send, through the interface circuit 1002, information obtained through processing.

Optionally, the chip further includes a memory. The memory may include a read-only memory and a random access memory, and provide operation instructions and data for the processor. A part of the memory may further include a non-volatile random access memory (non-volatile random access memory, NVRAM).

Optionally, the memory stores an executable software module or a data structure. The processor may perform a corresponding operation by invoking the operation instructions stored in the memory (the operation instructions may be stored in an operating system).

Optionally, the chip may be used in a memory control apparatus in embodiments of this application. Optionally, the interface circuit 1002 may be configured to output an execution result of the processor 1001. For the memory control method provided in one or more embodiments of this application, refer to the foregoing embodiments. Details are not described herein again.

It should be noted that functions respectively corresponding to the processor 1001 and the interface circuit 1002 may be implemented by using a hardware design, may be implemented by using a software design, or may be implemented in a combination of software and hardware. This is not limited herein.

An embodiment of this application further provides an electronic device. The electronic device includes the control apparatus 130 shown in FIG. 2 and the connection apparatus 140 shown in FIG. 2.

For example, the electronic device may be a foldable device.

An embodiment of this application further provides a computer storage medium. The computer storage medium stores computer instructions. When the computer instructions are run on a memory control apparatus, the memory control apparatus is enabled to perform the foregoing related method steps to implement the memory control method in the foregoing embodiments.

An embodiment of this application further provides a computer program product. When the computer program product runs on a computer, the computer is enabled to perform the foregoing related steps to implement the memory control method in the foregoing embodiments.

An embodiment of this application further provides a memory control apparatus. The apparatus may be specifically a chip, an integrated circuit, a component, or a module. Specifically, the apparatus may include a connected processor and a memory configured to store instructions, or the apparatus includes at least one processor, configured to obtain instructions from an external memory. When the apparatus runs, the processor may execute the instructions, and the chip is enabled to perform the memory control method in the foregoing method embodiments.

It should be understood that sequence numbers of the foregoing processes do not mean execution sequences in various embodiments of this application. The execution sequences of the processes should be determined based on functions and internal logic of the processes, and should not be construed as any limitation on the implementation processes of embodiments of this application.

A person of ordinary skill in the art may be aware that, in combination with the examples described in embodiments disclosed in this specification, units and algorithm steps may be implemented by electronic hardware or a combination of computer software and electronic hardware. Whether the functions are performed by hardware or software depends on particular applications and design constraint conditions of the technical solutions. A person skilled in the art may use different methods to implement the described functions for each particular application, but it should not be considered that the implementation goes beyond the scope of this application.

It may be clearly understood by a person skilled in the art that, for the purpose of convenient and brief description, for a detailed working process of the foregoing system, apparatus, and unit, refer to a corresponding process in the foregoing method embodiments. Details are not described herein again.

In several embodiments provided in this application, it should be understood that the disclosed system, apparatus, and method may be implemented in another manner. For example, the described apparatus embodiment is merely an example. For example, division into the units is merely logical function division and may be other division during actual implementation. For example, a plurality of units or components may be combined or integrated into another system, or some features may be ignored or not performed. In addition, the displayed or discussed mutual couplings, direct couplings, or communication connections may be implemented through some interfaces. The indirect couplings or communication connections between the apparatuses or units may be implemented in electronic, mechanical, or another form.

The units described as separate components may or may not be physically separate, and components displayed as units may or may not be physical units, and may be located in one position, or may be distributed on a plurality of network units. Some or all of the units may be selected according to actual requirements to achieve the objectives of the solutions of embodiments.

In addition, functional units in embodiments of this application may be integrated into one processing unit, each of the units may exist alone physically, or two or more units may be integrated into one unit.

When the functions are implemented in a form of a software functional unit and sold or used as an independent product, the functions may be stored in a computer-readable storage medium. Based on such an understanding, the technical solutions of this application essentially, the part contributing to the conventional technology, or some of the technical solutions may be implemented in a form of a software product. The computer software product is stored in a storage medium, and includes several instructions for instructing a computing device (which may be a personal computer, a server, a network device, or the like) to perform all or some of the steps of the methods described in embodiments of this application. The foregoing storage medium includes any medium that can store program code, for example, a USB flash drive, a removable hard disk, a read-only memory (Read-Only Memory, ROM), a random access memory (Random Access Memory, RAM), a magnetic disk, or an optical disc.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1. A control apparatus for a connection apparatus in a foldable device, wherein the control apparatus comprises:
a processor, located on a first circuit board corresponding to a first screen in the foldable device, and configured to generate a control signal, wherein the control signal is used to control an operating mode of the connection apparatus, and the connection apparatus is located on a second circuit board corresponding to a second screen in the foldable device, and is configured to transmit a system signal between the first circuit board and the second circuit board; and
a transmission interface, configured to send the control signal to the connection apparatus.

2. The control apparatus according to claim 1, wherein the control signal comprises a sleep control signal, the sleep control signal is used to control the connection apparatus to enter a sleep mode, and the connection apparatus stops transmitting the system signal in the sleep mode.

3. The control apparatus according to claim 2, wherein the processor is specifically configured to:
generate the sleep control signal when it is determined that the system signal does not need to be transmitted between the first circuit board and the second circuit board.

4. The control apparatus according to claim 2, wherein the processor is further configured to:
control the transmission interface to enter a sleep mode.

5. The control apparatus according to claim 1, wherein the control signal comprises a working control signal, the working control signal is used to control the connection apparatus to enter a working mode, and the connection apparatus is configured to transmit the system signal in the working mode.

6. The control apparatus according to claim 5, wherein the processor is specifically configured to:
generate the working control signal when it is determined that the system signal needs to be transmitted between the first circuit board and the second circuit board.

7. The control apparatus according to claim 5, wherein the processor is further configured to:
control the transmission interface to enter a working mode.

8. The control apparatus according to claim 1, wherein the connection apparatus is configured to: receive the system signal from the first circuit board, and convert the system signal into one or more element control signals, wherein the one or more element control signals are used to control one or more functional elements on the second circuit board.

9. A connection apparatus for a foldable device, wherein the connection apparatus is located on a second circuit board corresponding to a second screen in the foldable device, and comprises:
a signal transmission circuit, configured to transmit a system signal between a first circuit board and the second circuit board in the foldable device; and
a controller, configured to receive a control signal from a control apparatus, and control an operating mode of the connection apparatus based on the control signal, wherein the control apparatus is located on the first circuit board.

10. The connection apparatus according to claim 9, wherein the control signal comprises a sleep control signal, and the sleep control signal is used to control the connection apparatus to enter a sleep mode; and
the signal transmission circuit is configured to: in the sleep mode, stop transmitting the system signal.

11. The connection apparatus according to claim 9, wherein the control signal comprises a working control signal, and the working control signal is used to control the connection apparatus to enter a working mode; and
the signal transmission circuit is configured to: in the working mode, transmit the system signal.

12. The connection apparatus according to claim 9, wherein the signal transmission circuit is configured to: receive the system signal from the first circuit board, and convert the system signal into one or more element control signals, wherein the one or more element control signals are used to control one or more functional elements on the second circuit board.

13. A control method, wherein the method comprises:
generating a control signal, wherein the control signal is used to control an operating mode of a connection apparatus, and the connection apparatus is located on a second circuit board corresponding to a second screen in a foldable device, and is configured to transmit a system signal between a first circuit board and the second circuit board; and
sending the control signal to the connection apparatus.

14. The method according to claim 13, wherein the control signal comprises a sleep control signal or a working control signal, the sleep control signal is used to control the connection apparatus to enter a sleep mode, the connection apparatus stops transmitting the system signal in the sleep mode, the working control signal is used to control the connection apparatus to enter a working mode, and the connection apparatus is configured to transmit the system signal in the working mode.
